(19) United States
(12) Patent Application Publication
(10) Pub. No.: US 2026/0293287 A1
(43) Pub. Date: Sep. 24, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yoko Iwakaji, Meguro Tokyo (JP); Keiko Kawamura, Yokohama Kanagawa (JP); Kazutoshi Nakamura, Nonoichi Ishikawa (JP); Daiki Yoshikawa, Nonoichi Ishikawa (JP)

(21) Appl. No.: 19/278,240

(22) Filed: Jul. 23, 2025

(30) Foreign Application Priority Data
Mar. 19, 2025 (JP) 2025-044884

(51) Int. Cl. H10D 84/00; H10D 8/00; H10D 12/00; H10D 62/10

(52) U.S. Cl. CPC H10D 84/161; H10D 8/422; H10D 12/481; H10D 62/103; H10D 62/126

(57) ABSTRACT

According to one embodiment, a semiconductor device includes first and second electrodes and a semiconductor layer therebetween. The semiconductor layer includes first to third regions. The semiconductor layer includes first to eight semiconductor regions. The first and second semiconductor regions are provided in the first and second regions, respectively. The third semiconductor region is provided thereon. Multiple fifth semiconductor regions of a second conductivity type provided on the third semiconductor region. Multiple gate electrodes respectively face the fifth semiconductor regions via gate insulating layers. Multiple sixth semiconductor regions are respectively provided on the fifth semiconductor regions. The sixth semiconductor regions are respectively in contact with multiple contact portions of the second electrode. The eighth semiconductor region of the second conductivity type and the ninth semiconductor region of a first conductivity type each provided between another one of the fifth semiconductor regions and another one of the contact portions.

### CROSS-REFERENCE TO RELATED APPLICATIONS

This application is based upon and claims the benefit of priority from Japanese Patent Application No. 2025-044884, filed on Mar. 19, 2025; the entire contents of which are incorporated herein by reference.

### FIELD

Embodiments of the present invention generally relate to a semiconductor device.

### BACKGROUND

There is a semiconductor device (Reverse-Conducting IGBT: RC-IGBT) that has the functions of an insulated gate bipolar transistor (IGBT) and the function of a diode. There is a need for a technology to reduce switching losses during diode operation in such semiconductor devices.

### BRIEF DESCRIPTION OF THE DRAWINGS

FIG. 1 is a plan view of a semiconductor device according to a first embodiment;

FIG. 2 is an enlarged plan view of portion II of FIG. 1;

FIG. 3 is a III-III cross-sectional view of FIG. 2;

FIG. 4 is a IV-IV cross-sectional view of FIG. 2;

FIG. 5 is an enlarged plan view of a part of the semiconductor device according to the first embodiment;

FIG. 6 is an enlarged plan view of a part of the semiconductor device according to the first embodiment;

FIG. 7 is an enlarged plan view of a part of the semiconductor device according to the first embodiment;

FIGS. 8A and 8B are enlarged plan views illustrating an example of portions VIIIA and VIIIB of FIG. 1;

FIGS. 9A and 9B are enlarged plan views illustrating another example of portions VIIIA and VIIIB of FIG. 1;

FIGS. 10A and 10B are enlarged plan views illustrating still another example of portions VIIIA and VIIIB of FIG. 1;

FIG. 11 is a plan view illustrating a part of a semiconductor device according to a modification of the first embodiment;

FIG. 12 is a plan view illustrating a part of a semiconductor device according to a second embodiment;

FIG. 13 is a XIII-XIII cross-sectional view of FIG. 12;

FIG. 14 is a XIV-XIV cross-sectional view of FIG. 12;

FIG. 15 is a plan view illustrating a part of a semiconductor device according to a third embodiment;

FIG. 16 is a XVI-XVI cross-sectional view of FIG. 14; and

FIG. 17 is a XVII-XVII cross-sectional view of FIG. 15.

### DETAILED DESCRIPTION

According to one embodiment, a semiconductor device includes a first electrode, a second electrode, and a semiconductor layer. The second electrode is apart from the first electrode in a first direction. The semiconductor layer is provided between the first electrode and the second electrode. The semiconductor layer includes a first region, a second region, and a third region. The third region is located between the first region and the second region in a second direction that is perpendicular to the first direction. The semiconductor layer includes a first semiconductor region of a first conductivity type, a second semiconductor region of a second conductivity type, a third semiconductor region of the first conductivity type, a fourth semiconductor region of the second conductivity type, a plurality of fifth semiconductor regions of the second conductivity type, a plurality of gate electrodes, a plurality of sixth semiconductor regions of the first conductivity type, a seventh semiconductor region of the second conductivity type, an eighth semiconductor region of the second conductivity type, and a ninth semiconductor region of the first conductivity type. The first semiconductor region is provided in the first region. The second semiconductor region is provided in the second region. The third semiconductor region is provided on the first semiconductor region and the second semiconductor region. The fourth semiconductor region is provided on the third semiconductor region. The fourth semiconductor region is located in the first region. The plurality of fifth semiconductor regions are provided on the third semiconductor region. The plurality of fifth semiconductor regions are located in the second region and the third region. The plurality of gate electrodes respectively face the plurality of fifth semiconductor regions via a plurality of gate insulating layers in the second direction. The plurality of sixth semiconductor regions are respectively provided on the plurality of fifth semiconductor regions. The plurality of sixth semiconductor regions are respectively in contact with a plurality of contact portions of the second electrode in the second direction. The seventh semiconductor region is provided between one of the plurality of fifth semiconductor regions and one of the plurality of contact portions in the second region. The eighth semiconductor region and the ninth semiconductor region are each provided between another one of the plurality of fifth semiconductor regions and another one of the plurality of contact portions in the third region.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, the notations n⁺, n⁻ and p⁺, p represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them.

N-type is an example of the first conductivity type. P-type is an example of the second conductivity type. The embodiments described below may be implemented by reversing the p-type and the n-type of the semiconductor regions.

### First Embodiment

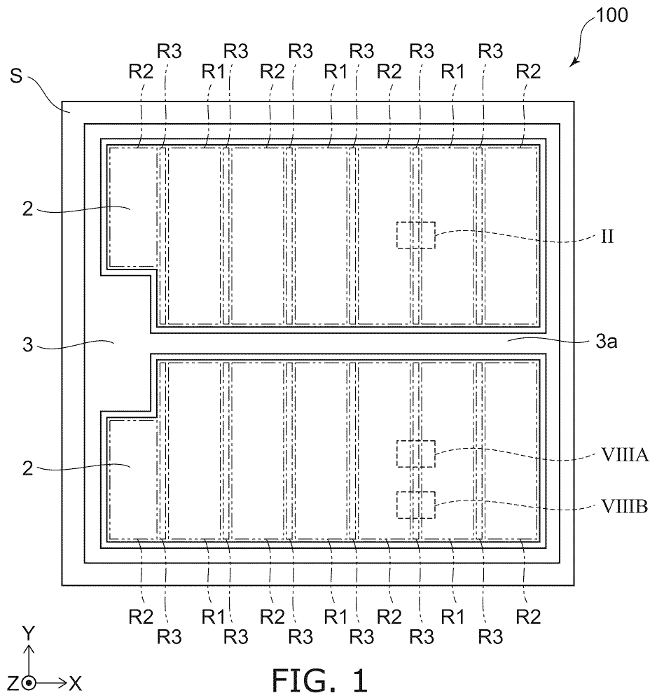

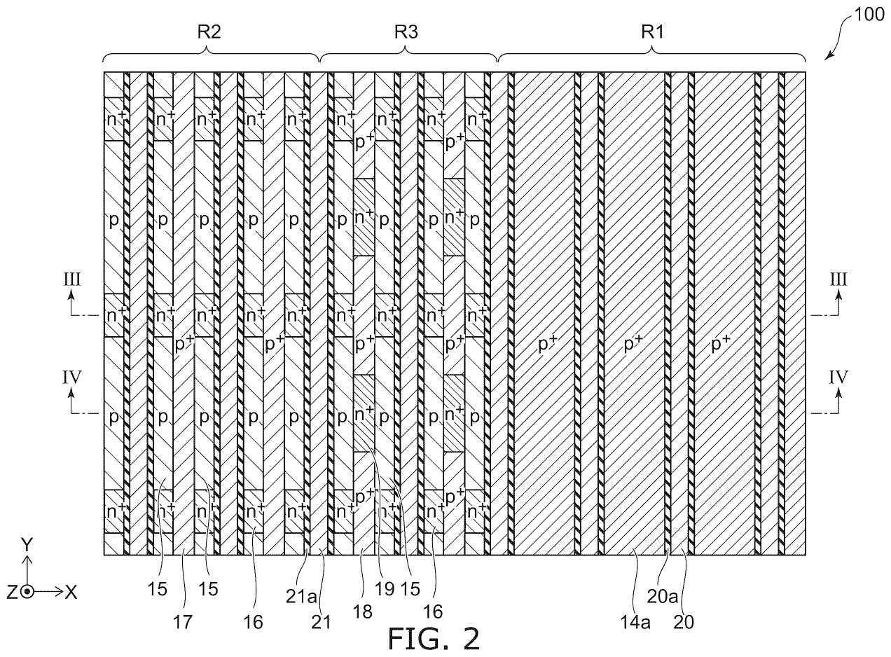

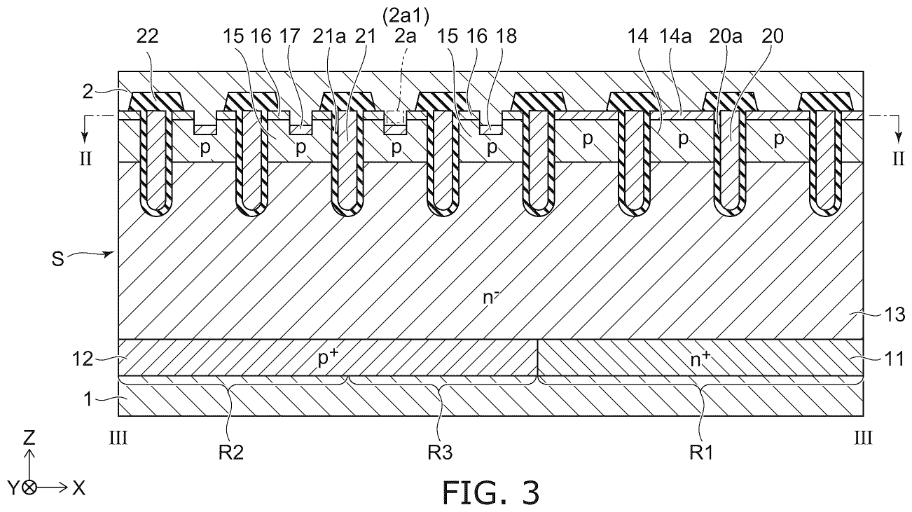

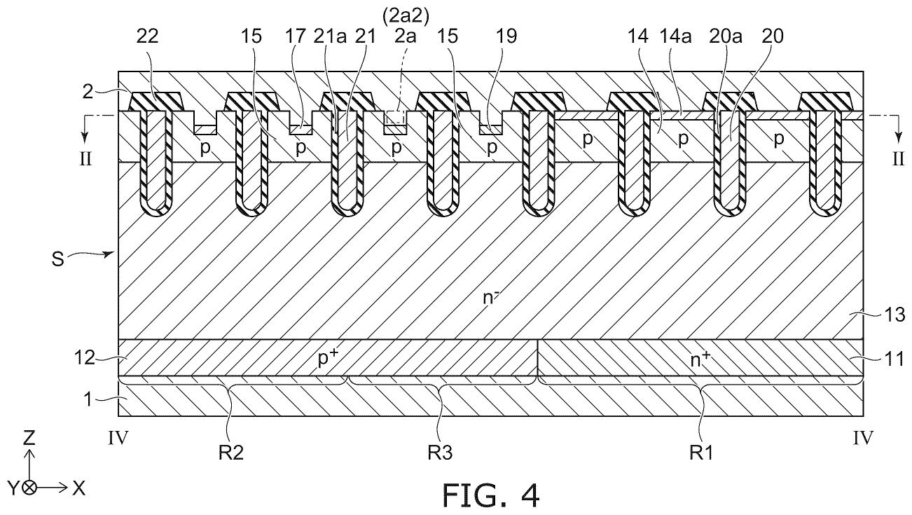

FIG. 1 is a plan view of a semiconductor device according to a first embodiment. FIG. 2 is an enlarged plan view of portion II of FIG. 1. FIG. 3 is a III-III cross-sectional view of FIG. 2. FIG. 4 is a IV-IV cross-sectional view of FIG. 2. FIG. 2 corresponds to a II-II cross-sectional view of FIGS. 3 and 4.

The semiconductor device of the embodiment is an RC-IGBT. As shown in FIGS. 1 to 4, the semiconductor device 100 according to the embodiment includes a collector electrode 1 (a first electrode), an emitter electrode 2 (a second electrode), a gate pad 3, and a semiconductor layer S. Note that the emitter electrode 2 is omitted in FIG. 2.

An XYZ orthogonal coordinate system is used in the description of the embodiments. A direction from the collector electrode 1 toward the emitter electrode 2 is taken as a Z-direction (a first direction). Two mutually-orthogonal directions perpendicular to the Z-direction are taken as an X-direction (a second direction) and a Y-direction (a third direction). In the description, the direction from the collector electrode 1 toward the emitter electrode 2 is referred to as “up/above”, and the opposite direction is referred to as “down/below”. These directions are based on the relative positional relationship between the collector electrode 1 and the emitter electrode 2, and are independent of the direction of gravity.

As shown in FIG. 1, the emitter electrode 2 and the gate pad 3 are provided on the upper surface of the semiconductor device 100. The emitter electrode 2 and the gate pad 3 are apart from each other. For example, a plurality of emitter electrodes 2 are provided in the Y-direction. Gate wiring 3a is provided around each emitter electrode 2. A part of the gate wiring 3a extends in the Y-direction between the emitter electrodes 2. The gate wiring 3a is electrically connected to the gate pad 3. The semiconductor layer S is provided below the emitter electrode 2, the gate pad 3, and the gate wiring 3a.

As shown in FIGS. 1 and 2, the semiconductor layer S includes a diode region R1 (a first region), an IGBT region R2 (a second region), and an IGBT region R3 (a third region). In the illustrated example, a plurality of diode regions R1 and a plurality of IGBT regions R2 are provided in the X-direction and Y-direction. In the X-direction, the diode region R1 and the IGBT region R2 are alternately provided. The IGBT region R3 is provided between the diode region R1 and the IGBT region R2.

As shown in FIGS. 3 and 4, the collector electrode 1 is provided on the lower surface of the semiconductor device 100. The collector electrode 1 and the emitter electrode 2 are apart from each other in the Z-direction. The semiconductor layer S is located between the collector electrode 1 and the emitter electrode 2.

The semiconductor layer S includes an n⁺-type cathode region 11 (a first semiconductor region), a p⁺-type collector region 12 (a second semiconductor region), an n⁻-type base region 13 (a third semiconductor region), a p-type anode region 14 (a fourth semiconductor region), a p⁺-type anode region 14a, a p-type base region 15 (a fifth semiconductor region), an n⁺-type emitter region 16 (a sixth semiconductor region), a p⁺-type contact region 17 (a seventh semiconductor region), a p⁺-type contact region 18 (an eighth semiconductor region), an n⁺-type contact region 19 (a ninth semiconductor region), a conductive portion 20, and a gate electrode 21.

The n⁺-type cathode region 11 is provided in the diode region R1. The p⁺-type collector region 12 is provided in the IGBT region R2. The n⁻-type base region 13 is provided on the n⁺-type cathode region 11 and the p⁺-type collector region 12. The n-type impurity concentration in the n⁻-type base region 13 is lower than the n-type impurity concentration in the n⁺-type cathode region 11.

In the IGBT region R3, the p⁺-type collector region 12 may be provided between the collector electrode 1 and the n⁻-type base region 13 as illustrated. Alternatively, in the IGBT region R3, the n⁺-type cathode region 11, or both the n⁺-type cathode region 11 and the p⁺-type collector region 12, may be provided between the collector electrode 1 and the n⁻-type base region 13.

The p-type anode region 14 is provided on the n⁻-type base region 13 in the diode region R1. The p⁺-type anode region 14a is provided on the p-type anode region 14. The p-type impurity concentration in the p⁺-type anode region 14a is higher than the p-type impurity concentration in the p-type anode region 14. The conductive portion 20 faces the p-type anode region 14 in the X-direction via an insulating layer 20a. The p-type anode region 14 and the conductive portion 20 are alternately provided in the X-direction, and each p-type anode region 14 and each conductive portion 20 extend in the Y-direction.

The p-type base region 15 is provided on the n⁻-type base region 13 in the IGBT region R2. The gate electrode 21 faces the p-type base region 15 in the X-direction via a gate insulating layer 21a. The p-type base region 15 and the gate electrode 21 are alternately provided in the X-direction, and each p-type base region 15 and each gate electrode 21 extend in the Y-direction.

A plurality of n⁺-type emitter regions 16 are respectively provided on the plurality of p-type base regions 15. The emitter electrode 2 includes a plurality of contact portions 2a that protrude toward the semiconductor layer S. The plurality of n⁺-type emitter regions 16 are in contact with the plurality of contact portions 2a in the X-direction, respectively. In other words, on one p-type base region 15, at least one n⁺-type emitter region 16 and one contact portion 2a are provided. A plurality of groups, each including one p-type base region 15, at least one n⁺-type emitter region 16, and one contact portion 2a, are provided along the X-direction.

For example, as shown in FIG. 2, a pair of n⁺-type emitter regions 16, spaced apart in the X-direction, are provided on one p-type base region 15. In the Y-direction, a plurality of pairs of n⁺-type emitter regions 16 are provided apart from each other. Between each pair of n⁺-type emitter regions 16 in the X-direction, the contact portion 2a extends along the Y-direction.

As shown in FIGS. 3 and 4, in the IGBT region R2, the p⁺-type contact region 17 is provided between the p-type base region 15 and the contact portion 2a. The p-type impurity concentration in the p⁺-type contact region 17 is higher than the p-type impurity concentration in the p-type base region 15. The p⁺-type contact region 17 extends in the Y-direction.

In the IGBT region R3, the p⁺-type contact region 18 and the n⁺-type contact region 19 are provided between the p-type base region 15 and the contact portion 2a. The p-type impurity concentration in the p⁺-type contact region 18 is higher than the p-type impurity concentration in the p-type base region 15. The n-type impurity concentration in the n⁺-type contact region 19 is higher than the n-type impurity concentration in the n⁻-type base region 13. The n-type impurity concentration in the n⁺-type contact region 19 may be equal to or lower than the n-type impurity concentration in the n⁺-type emitter region 16. The p⁺-type contact region 18 and the n⁺-type contact region 19 are arranged with each other in the Y-direction. For example, as shown in FIG. 2, the p⁺-type contact region 18 and the n⁺-type contact region 19 are alternately provided in the Y-direction.

As shown in FIGS. 3 and 4, the contact portion 2a includes a first portion 2a1 located on the p⁺-type contact region 18 and a second portion 2a2 located on the n⁺-type contact region 19.

The emitter electrode 2 is located on the p-type anode region 14, the p⁺-type anode region 14a, the p-type base region 15, the n⁺-type emitter region 16, the p⁺-type contact region 17, the p⁺-type contact region 18, and the n⁺-type contact region 19, and is electrically connected to these semiconductor regions. The conductive portion 20 is electrically connected to the emitter electrode 2 in an unillustrated portion. The gate electrode 21 is electrically isolated from the emitter electrode 2 by an insulating layer 22. The gate electrode 21 is electrically connected to the gate wiring 3a in an unillustrated portion.

The operation of the semiconductor device 100 will be described.

In a state where a positive voltage is applied to the collector electrode 1 with respect to the emitter electrode 2, a voltage not less than the threshold value is applied to the gate electrode 21. As a result, a channel (an inversion layer) is formed in the p-type base region 15. Electrons are injected from the n⁺-type emitter region 16 into the n⁻-type base region 13 through the channel, and holes are injected from the p⁺-type collector region 12 into the n⁻-type base region 13. The carrier density accumulated in the n⁻-type base region 13 increases, and conductivity modulation occurs. As a result, the electrical resistance of the n⁻-type base region 13 is greatly reduced, and the IGBT regions R2 and R3 are turned on. Thereafter, when the voltage applied to the gate electrode 21 becomes lower than the threshold value, the channel in the p-type base region 15 disappears, and the IGBT regions R2 and R3 switch to the off-state. After the IGBT regions R2 and R3 switch to the off-state, the electrons that had been accumulated in the n⁻-type base region 13 are discharged to the collector electrode 1 through the p⁺-type collector region 12. The holes are discharged to the emitter electrode 2 through the p-type base region 15.

For example, a bridge circuit is configured using a plurality of semiconductor devices 100. When the IGBT regions R2 and R3 of one semiconductor device 100 switch from the on-state to the off-state, an electromotive force is induced in the emitter electrode 2 of another semiconductor device 100 due to the inductance of the bridge circuit. As a result, in the other semiconductor device 100, the diode region R1 operates. Holes are injected from the p-type anode region 14 into the n⁻-type base region 13, and electrons are injected from the n⁺-type cathode region 11 into the n⁻-type base region 13. The diode region R1 functions as a freewheeling diode (FWD).

An example of a material of each component of the semiconductor device 100 will be described.

The collector electrode 1, the emitter electrode 2, the gate pad 3, and the gate wiring 3a include a metal material such as aluminum or copper. The n⁺-type cathode region 11, the p⁺-type collector region 12, the n⁻-type base region 13, the p-type anode region 14, the p⁺-type anode region 14a, the p-type base region 15, the n⁺-type emitter region 16, the p⁺-type contact region 17, the p⁺-type contact region 18, and the n⁺-type contact region 19 include a semiconductor material such as silicon, silicon carbide, gallium nitride, or gallium arsenide. When silicon is used as the semiconductor material, arsenic, phosphorus, or antimony can be used as the n-type impurity. Boron can be used as the p-type impurity. The conductive portion 20 and the gate electrode 21 include a conductive material such as conductive polysilicon doped with impurities. The insulating layer 20a, the gate insulating layer 21a, and the insulating layer 22 include an insulating material such as silicon oxide, silicon nitride, or silicon oxynitride.

The semiconductor device 100 has a parasitic thyristor including the p⁺-type collector region 12, the n⁻-type base region 13, the p-type base region 15, and the n⁺-type emitter region 16. When the IGBT regions R2 and R3 are turned off, holes flow into the p-type base region 15. If the electric potential of the p-type base region 15 increases due to the inflow of holes, the parasitic thyristor may operate. The semiconductor device 100 includes the p⁺-type contact region 17 and the p⁺-type contact region 18 for suppressing the operation of the parasitic thyristor. The p-type impurity concentrations in the p⁺-type contact region 17 and the p⁺-type contact region 18 are higher than the p-type impurity concentration in the p-type base region 15. By providing the p⁺-type contact region 17 and p⁺-type contact region 18, holes are more easily discharged to the emitter electrode 2 through these semiconductor regions. As a result, the rise in electric potential of the p-type base region 15 is suppressed, and the operation of the parasitic thyristor is suppressed.

On the other hand, the IGBT regions R2 and R3 have a parasitic diode including the n⁻-type base region 13 and the p-type base region 15. When the diode region R1 is in the on-state, the parasitic diodes of the IGBT regions R2 and R3 operate, and holes are injected from the emitter electrode 2 into the n⁻-type base region 13. In particular, in the IGBT region R3 adjacent to the diode region R1, more holes are injected into the n⁻-type base region 13 through the p⁺-type contact region 18. Consequently, during the operation of the diode region R1, carriers accumulated in the n⁻-type base region 13 increase. When the diode region R1 switches to the off-state, it takes a longer time to discharge the carriers accumulated in the n⁻-type base region 13. As a result, during the reverse recovery of the diode region R1, the switching loss of the semiconductor device 100 increases.

Regarding this issue, in the semiconductor device 100, the n⁺-type contact region 19 is provided in the IGBT region R3. The n⁺-type contact region 19 is located between the p-type base region 15 and the contact portion 2a. In the IGBT region R3, a part of the p⁺-type contact region is replaced by n⁺-type contact region 19, unlike in the IGBT region R2. When the n⁺-type contact region 19 is provided, the contact area between the p⁺-type contact region 18 and the contact portion 2a becomes smaller than in the case where the p⁺-type contact region 18 extends continuously in the Y-direction like the p⁺-type contact region 17. Additionally, since the n⁺-type contact region 19 has a conductivity type opposite to that of the p-type base region 15 and the p⁺-type contact region 18, hole injection is suppressed in the portion where the n⁺-type contact region 19 is provided. By providing the n⁺-type contact region 19, the amount of holes injected from the IGBT region R3 during operation of the diode region R1 can be reduced. Furthermore, during the operation of the diode region R1, a part of the electrons accumulated in the n⁻-type base region 13 is discharged to the emitter electrode 2 through the n⁺-type contact region 19. Thus, during the operation of the diode region R1, the carrier density accumulated in the n⁻-type base region 13 can be reduced.

According to the first embodiment, during the operation of the diode, the injection of holes can be suppressed and the discharge of electrons can be facilitated in the IGBT region R3. As a result, the reverse recovery current during the reverse recovery of the diode region R1 can be reduced, and the switching loss of the semiconductor device 100 can be decreased.

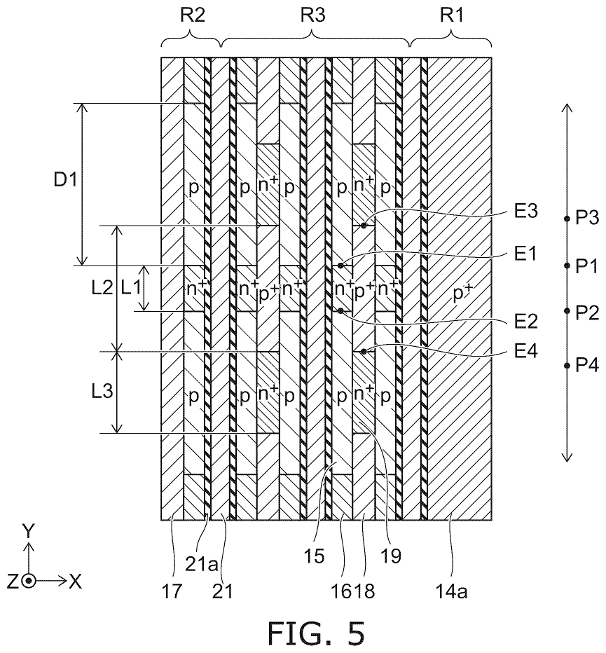

FIGS. 5 to 7 are enlarged plan views of a part of the semiconductor device according to the first embodiment.

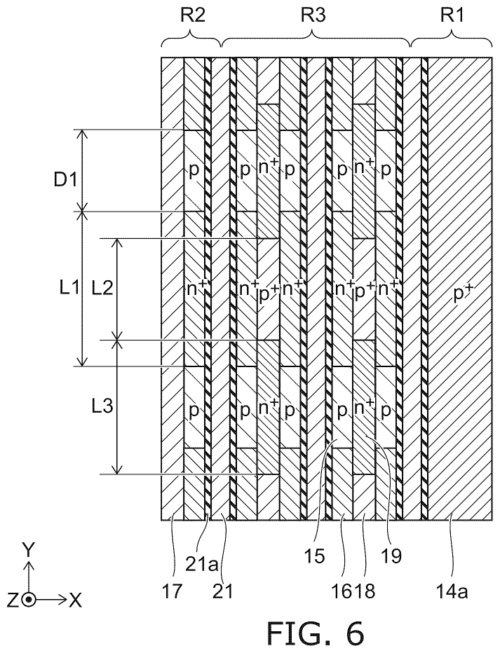

In the semiconductor device 100, a part of the p-type base region 15 is provided between the n⁺-type emitter regions 16 in the Y-direction. For example, as shown in FIG. 5, the distance D1 in the Y-direction between the n⁺-type emitter regions 16 is longer than the length L1 in the Y-direction of one n⁺-type emitter region 16. Alternatively, as shown in FIG. 6, the distance D1 in the Y-direction between the n⁺-type emitter regions 16 may be shorter than the length L1 in the Y-direction of one n⁺-type emitter region 16.

The p⁺-type contact region 18 and the n⁺-type contact region 19 are alternately provided in the Y-direction on one p-type base region 15. For example, as shown in FIG. 5, the length L2 in the Y-direction of one p⁺-type contact region 18 is longer than the length L3 in the Y-direction of one n⁺-type contact region 19. Alternatively, as shown in FIG. 6, the length L2 in the Y-direction of one p⁺-type contact region 18 may be shorter than the length L3 in the Y-direction of one n⁺-type contact region 19.

According to the structure shown in FIG. 5, the distance D1 is longer than the length L1, and the area ratio of the n⁺-type emitter region 16 is small. When the area ratio of the n⁺-type emitter region 16 is small, the current flowing from the emitter electrode 2 to the collector electrode 1 through the n⁺-type emitter region 16 can be reduced. As a result, the saturation current of the semiconductor device 100 can be reduced. For example, the current flowing through the semiconductor device 100 during a short circuit can be reduced, and the occurrence of destruction due to the short circuit can be suppressed. In addition, the length L2 is longer than the length L3, and the area ratio of the p⁺-type contact region 18 is large. In the case where the area ratio of the p⁺-type contact region 18 is large, holes are more easily discharged through the p⁺-type contact region 18 when the IGBT regions R2 and R3 are turned-off, and the rise in electric potential of the p-type base region 15 is suppressed. Therefore, the operation of the parasitic thyristor can be suppressed in the IGBT region R3.

According to the structure shown in FIG. 6, the distance D1 is shorter than the length L1, and the area ratio of the n⁺-type emitter region 16 is large. When the area ratio of the n⁺-type emitter region 16 is large, more electrons are injected into the n⁻-type base region 13 through the n⁺-type emitter region 16 when the IGBT regions R2 and R3 are in the on-state. As a result, the switching loss during turn-on of the IGBT regions R2 and R3, as well as the steady-state loss during the on-state, can be reduced. In addition, the length L3 is longer than the length L2, and the area ratio of the n⁺-type contact region 19 is large. When the area ratio of the n⁺-type contact region 19 is large, the injection of holes through the p⁺-type contact region 18 during the operation of the diode region R1 is suppressed. Therefore, the switching loss of the semiconductor device 100 can be reduced.

As shown in FIGS. 5 and 6, it is preferable that the position in the Y-direction of at least a part of the n⁺-type emitter region 16 be the same as the position in the Y-direction of at least a part of the p⁺-type contact region 18. For example, in one cross-section perpendicular to the Y-direction, both the at least a part of the n⁺-type emitter region 16 and the at least a part of the p⁺-type contact region 18 are present. In this case, in plan view, the p⁺-type contact region 18 is located in at least a part of the region between a pair of n⁺-type emitter regions 16 arranged in the X-direction. Here, the term “plan view” refers to a view of the semiconductor device 100 from the Z-direction, with the emitter electrode 2 and the insulating layer 22 omitted.

In other words, it is preferable that at least a part of the first portion 2a1 of the contact portion 2a is located between the pair of n⁺-type emitter regions 16. When the IGBT regions R2 and R3 are turned off, holes are discharged to the emitter electrode 2 through the p⁺-type contact region 18 in the IGBT region R3. The amount of holes passing through the n⁺-type contact region 19 is less than the amount of holes passing through the p⁺-type contact region 18. Therefore, in the vicinity of the n⁺-type contact region 19, the electric potential of the p-type base region 15 tends to rise more easily compared to the vicinity of the p⁺-type contact region 18. When at least a part of the first portion 2a1 is located between the pair of n⁺-type emitter regions 16, holes are easily discharged through the p⁺-type contact region 18 which is positioned directly below the first portion 2a1. The rise in the electric potential of the p-type base region 15 in the vicinity of the n⁺-type emitter region 16 is suppressed. As a result, the operation of the parasitic thyristor can be suppressed.

More preferably, in plan view, in the region between the pair of n⁺-type emitter regions 16 arranged in the X-direction, the area in which the p⁺-type contact region 18 is provided is greater than the area in which the n⁺-type contact region 19 is provided. In other words, in the region between the pair of n⁺-type emitter regions 16 arranged in the X-direction, the area in the X-Y plane of the first portion 2a1 is greater than the area in the X-Y plane of the second portion 2a2. As a result, in the region between the pair of n⁺-type emitter regions 16, more holes can be discharged through the p⁺-type contact region 18, and the rise in electric potential of the p-type base region 15 in the vicinity of the n⁺-type emitter regions 16 can be suppressed.

Most preferably, as shown in FIG. 5, the p⁺-type contact region 18 is provided over the entire region between the pair of n⁺-type emitter regions 16 in plan view. In other words, it is most preferable that the first portion 2a1 is provided over the entire region between the pair of n⁺-type emitter regions 16. In plan view, the n⁺-type contact region 19 is not located between the pair of n⁺-type emitter regions 16. More specifically, the n⁺-type emitter region 16 includes a first end E1 and a second end E2 in the Y-direction. The p⁺-type contact region 18 includes a third end E3 and a fourth end E4 in the Y-direction. The position P1 of the first end E1 in the Y-direction and the position P2 of the second end E2 in the Y-direction are between the position P3 of the third end E3 in the Y-direction and the position P4 of the fourth end E4 in the Y-direction. By providing the p⁺-type contact region 18 over the entire region between the pair of n⁺-type emitter regions 16, the rise in electric potential of the p-type base region 15 in the vicinity of the n⁺-type emitter regions 16 is further suppressed. As a result, the operation of the parasitic thyristor can be more effectively suppressed.

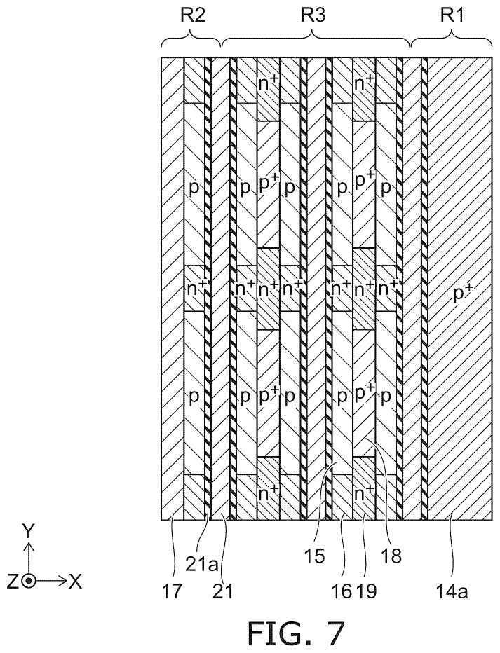

It should be noted that, in plan view, the n⁺-type contact region 19 may be provided over the entire region between the pair of n⁺-type emitter regions 16, as shown in FIG. 7. In this case, the injection of holes is also suppressed in the portion where the n⁺-type contact region 19 is provided, and the amount of holes injected from the IGBT region R3 during the operation of the diode region R1 can be reduced. In addition, during the operation of the diode region R1, electrons are discharged to the emitter electrode 2 through the n⁺-type contact region 19, thereby reducing the carrier density accumulated in the n⁻-type base region 13. As a result, the switching loss of the semiconductor device 100 can be reduced. However, from the viewpoint of suppressing the operation of the parasitic thyristor, the structures illustrated in FIGS. 5 and 6 are preferable, as described above.

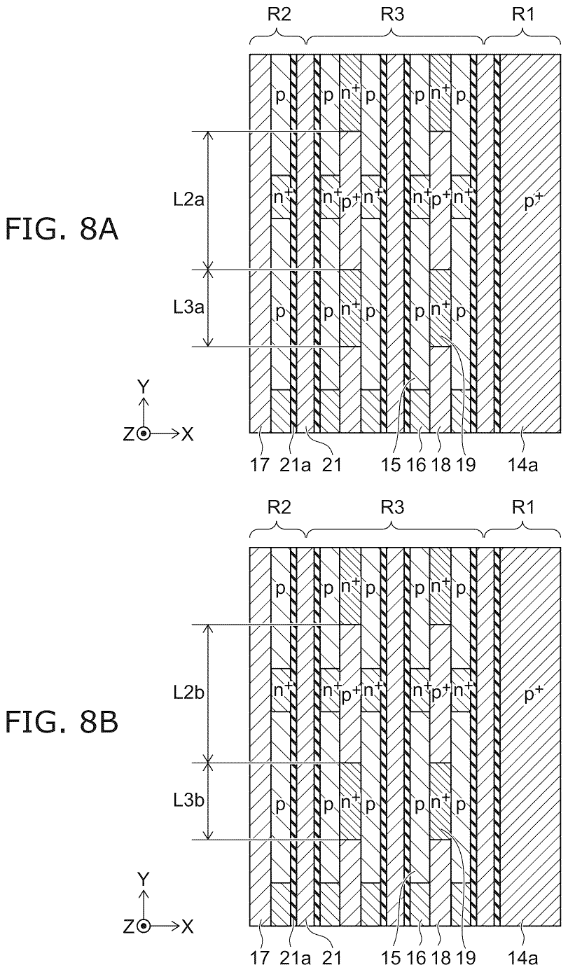

FIGS. 8A and 8B are enlarged plan views illustrating an example of portions VIIIA and VIIIB of FIG. 1. In FIGS. 8A and 8B, the emitter electrode 2 and the insulating layer 22 are omitted.

As shown in FIG. 1, the portion VIIIB is located between the portion VIIIA and the outer edge of the semiconductor device 100 in the Y-direction. The distance in the Y-direction between the portion VIIIB and the outer edge of the semiconductor device 100 is shorter than the distance in the Y-direction between the portion VIIIA and the outer edge of the semiconductor device 100. An outer peripheral region (a termination region) is provided at the outer periphery of the semiconductor layer S to improve the breakdown voltage of the semiconductor device 100. In the outer peripheral region, the diode region R1, the IGBT region R2, and the IGBT region R3 are not provided. The portion VIIIB is located on the outer peripheral region side of the semiconductor device 100 with respect to the portion VIIIA.

For example, as shown in FIGS. 8A and 8B, the length L2b of the p⁺-type contact region 18 in the portion VIIIB is the same as the length L2a of the p⁺-type contact region 18 in the portion VIIIA. The length L3b of the n⁺-type contact region 19 in the portion VIIIB is the same as the length L3a of the n⁺-type contact region 19 in the portion VIIIA. Throughout the IGBT region R3, the p⁺-type contact regions 18 and the n⁺-type contact regions 19 are provided at equal intervals.

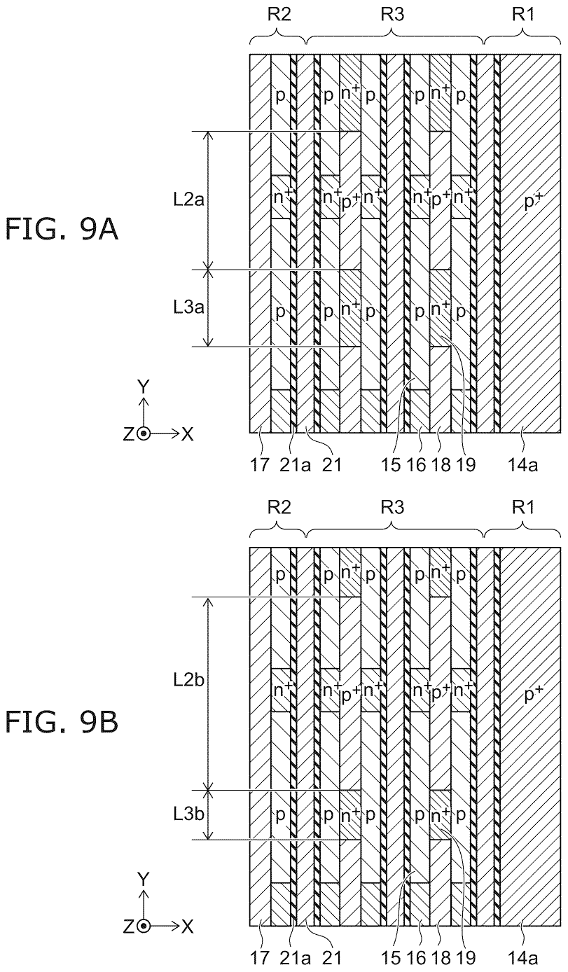

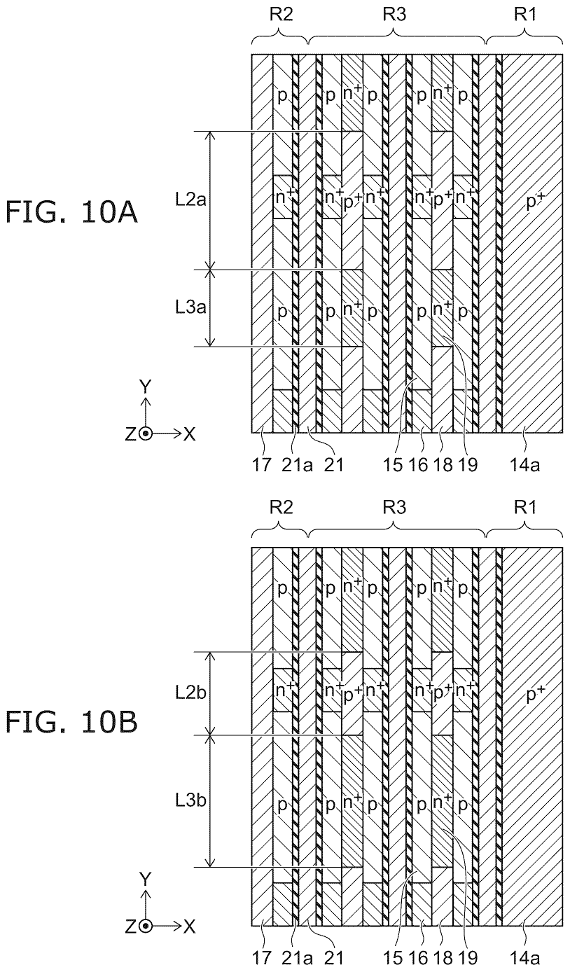

FIGS. 9A, 9B, 10A, and 10B are enlarged plan views illustrating another example of portions VIIIA and VIIIB of FIG. 1. In FIGS. 8A, 8B, 9A, and 9B, the emitter electrode 2 and the insulating layer 22 are omitted.

As shown in FIGS. 9A and 9B, the length L2b of the p⁺-type contact region 18 in the portion VIIIB may be longer than the length L2a of the p⁺-type contact region 18 in the portion VIIIA, and the length L3b of the n⁺-type contact region 19 in the portion VIIIB may be shorter than the length L3a of the n⁺-type contact region 19 in the portion VIIIA. In other words, in the example shown in FIGS. 9A and 9B, the closer to the outer peripheral region of the semiconductor device 100, the greater the area ratio of the p⁺-type contact region 18 becomes, and the smaller the area ratio of the n⁺-type contact region 19 becomes.

In the outer peripheral region of the semiconductor device 100, the emitter electrode 2 is not provided. When the IGBT regions R2 and R3 are turned off, holes accumulated in the outer peripheral region are discharged through the p⁺-type contact region 17 and the p⁺-type contact region 18 located near the outer peripheral region. Therefore, near the outer peripheral region, the electric potential of the p-type base region 15 tends to rise, and the parasitic thyristor is more likely to operate. As shown in FIGS. 9A and 9B, by increasing the area ratio of the p⁺-type contact region 18 as it gets closer to the outer peripheral region of the semiconductor device 100, the rise in electric potential of the p-type base region 15 near the outer peripheral region can be suppressed. As a result, the operation of the parasitic thyristor near the outer peripheral region can be suppressed.

Alternatively, as shown in FIGS. 10A and 10B, the length L2b of the p⁺-type contact region 18 in the portion VIIIB may be shorter than the length L2a of the p⁺-type contact region 18 in the portion VIIIA, and the length L3b of the n⁺-type contact region 19 in the portion VIIIB may be longer than the length L3a of the n⁺-type contact region 19 in the portion VIIIA. In other words, in the example shown in FIGS. 10A and 10B, the closer to the outer peripheral region of the semiconductor device 100, the smaller the area ratio of the p⁺-type contact region 18 becomes, and the greater the area ratio of the n⁺-type contact region 19 becomes.

When the diode region R1 switches from the on-state to the off-state, the electrons and holes accumulated in the n⁻-type base region 13 are discharged through the n⁺-type cathode region 11 and the p-type anode region 14, respectively. The holes accumulated in the termination region move to the diode region R1 and are discharged through the p-type anode region 14. Therefore, holes tend to accumulate in the p-type anode region 14 near the termination region. According to the structure shown in FIGS. 10A and 10B, the closer to the outer peripheral region of the semiconductor device 100, the smaller the area ratio of the p⁺-type contact region 18 becomes, and the greater the area ratio of the n⁺-type contact region 19 becomes. In this case, in the portion near the termination region, the injection of carriers during the operation of the diode region R1 can be suppressed. When the diode region R1 switches to the off-state, the amount of holes flowing into the p-type anode region 14 near the termination region can be reduced, and the occurrence of destruction of the semiconductor device 100 due to current crowding can be suppressed.

The emitter electrode 2 (the contact portion 2a) is in ohmic contact with the p⁺-type contact region 18 in the IGBT region R3. When the emitter electrode 2 is in ohmic contact with the p⁺-type contact region 18, the discharge of holes from the p⁺-type contact region 18 to the emitter electrode 2 can be facilitated. Since holes are more easily discharged to the emitter electrode 2 through the p⁺-type contact region 18, the operation of the parasitic thyristor can be suppressed.

The emitter electrode 2 (the contact portion 2a) may be in ohmic contact or Schottky contact with the n⁺-type contact region 19 in the IGBT region R3. It is preferable that the emitter electrode 2 (the contact portion 2a) is in Schottky contact with the n⁺-type contact region 19 in the IGBT region R3. When the emitter electrode 2 is in ohmic contact with the n⁺-type contact region 19, carriers can more easily move between the emitter electrode 2 and the n⁺-type contact region 19. As a result, for example, switching loss during reverse recovery operation of the diode in the semiconductor device 100 can be reduced.

When the emitter electrode 2 is in Schottky contact with the n⁺-type contact region 19, a potential barrier is formed between the emitter electrode 2 and the n⁺-type contact region 19. When the n⁺-type contact region 19 is provided, the thickness of the p-type base region 15 in the Z-direction becomes smaller in the lower portion of the contact portion 2a. In addition, due to the injection of n-type impurities for forming the n⁺-type contact region 19, the p-type impurity concentration in the p-type base region 15 may decrease. As a result, the breakdown voltage of the semiconductor device 100 may decrease. To address this issue, the formation of a potential barrier by Schottky contact can suppress the decrease in the breakdown voltage of the semiconductor device 100. For example, when the semiconductor layer S includes silicon as a semiconductor material, the emitter electrode 2 includes one or more selected from the group consisting of tungsten, platinum, gold, iridium, and aluminum.

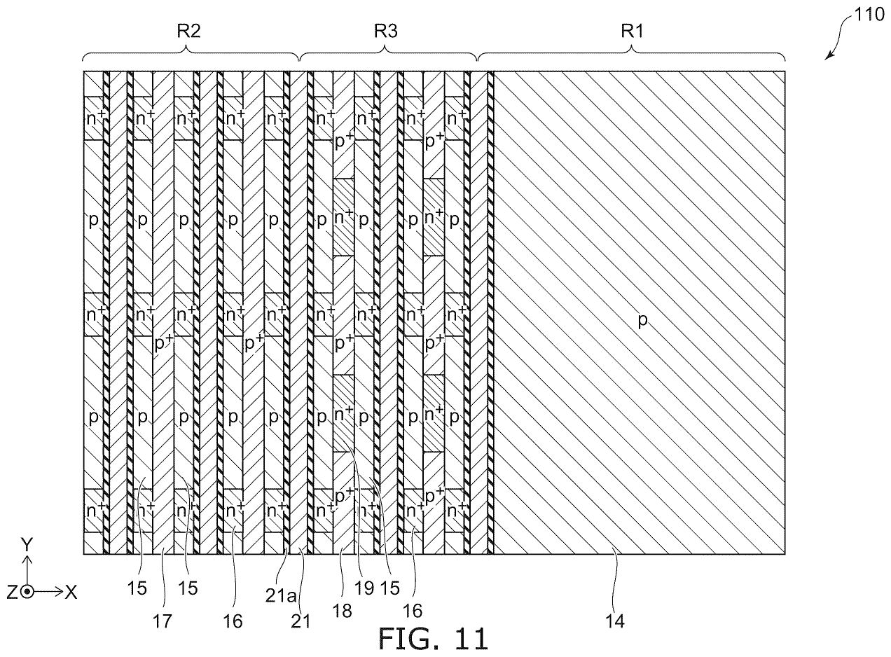

FIG. 11 is a plan view illustrating a part of a semiconductor device according to a modification of the first embodiment.

In the semiconductor device 110 shown in FIG. 11, the p⁺-type anode region 14a and the conductive portion 20 provided in the diode region R1 are omitted compared to those in the semiconductor device 100. As long as the n⁺-type contact region 19 is provided in the IGBT region R3, the specific configuration in the diode region R1 can be appropriately modified, as shown in FIG. 11.

### Second Embodiment

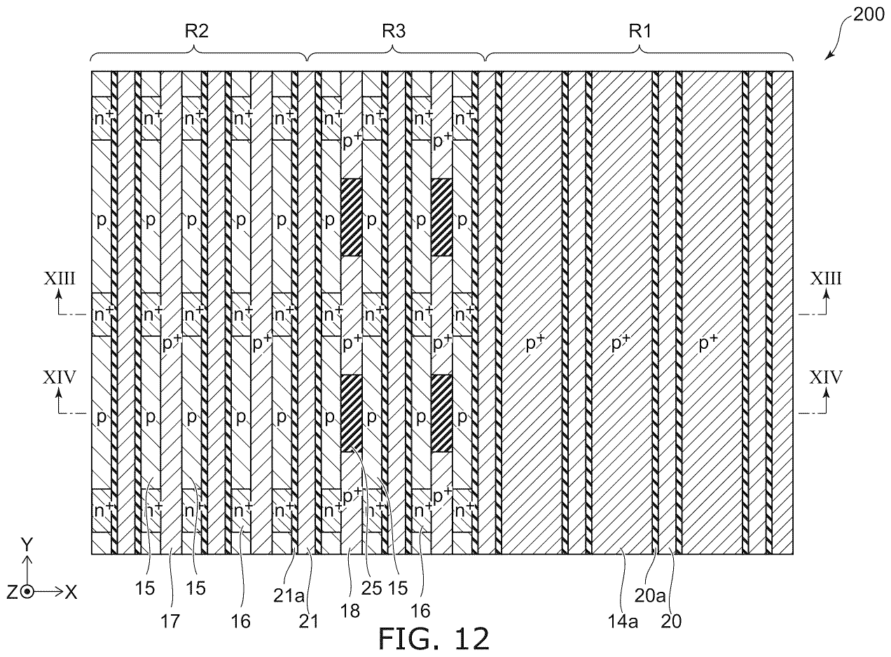

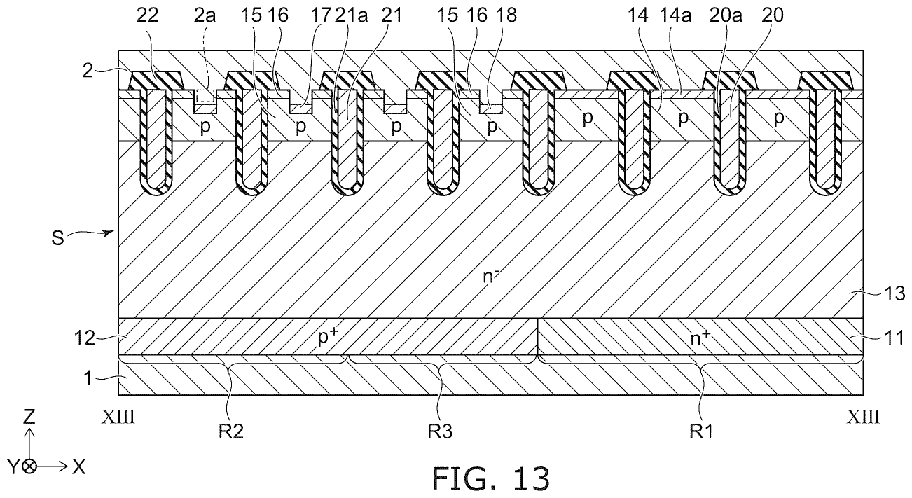

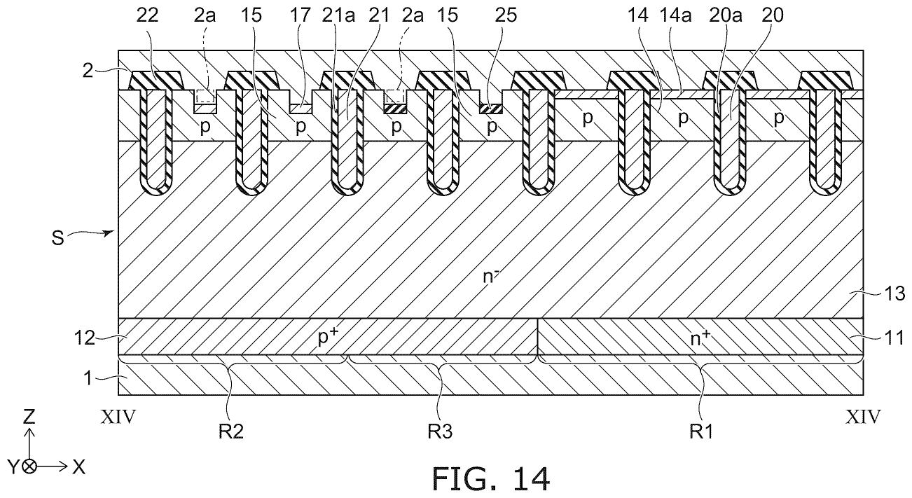

FIG. 12 is a plan view illustrating a part of a semiconductor device according to a second embodiment. FIG. 13 is a XIII-XIII cross-sectional view of FIG. 12. FIG. 14 is a XIV-XIV cross-sectional view of FIG. 12.

In the semiconductor device 200 according to the second embodiment, as shown in FIG. 12, an insulator 25 is provided in place of the n⁺-type contact region 19, as compared to the semiconductor device 100 according to the first embodiment.

The insulator 25 is arranged with the p⁺-type contact region 18 in the Y-direction. In other words, when viewed from the Y-direction, the insulator 25 overlaps with the p⁺-type contact region 18. As shown in FIG. 14, the insulator 25 is located between the p-type base region 15 and the contact portion 2a in the IGBT region R3. The insulator 25 includes an insulating material such as silicon oxide, silicon nitride, or silicon oxynitride.

The insulator 25 may be provided only below the contact portion 2a as shown in FIG. 14, or may be provided both below and beside the contact portion 2a. Preferably, in order to increase the contact area between the contact portion 2a and the p-type base region 15, the insulator 25 is provided only below the contact portion 2a.

As shown in FIGS. 12 to 14, the configurations other than the n⁺-type contact region 19 in the semiconductor device 100 can be applied to the configurations other than the insulator 25 in the semiconductor device 200.

For example, as in the example shown in FIG. 5, the length in the Y-direction of one p⁺-type contact region 18 may be longer than the length in the Y-direction of one insulator 25. Alternatively, as in the example shown in FIG. 6, the length in the Y-direction of one insulator 25 may be longer than the length in the Y-direction of one p⁺-type contact region 18. Also, as in the examples shown in FIGS. 5 and 6, it is preferable that the position in the Y-direction of at least a part of the n⁺-type emitter region 16 be the same as the position in the Y-direction of at least a part of the p⁺-type contact region 18. For example, in plan view, the p⁺-type contact region 18 is located in at least a part of the region between a pair of n⁺-type emitter regions 16 arranged in the X-direction.

More preferably, in plan view, in the region between the pair of n⁺-type emitter regions 16 arranged in the X-direction, the area where the p⁺-type contact region 18 is provided is greater than the area where the insulator 25 is provided. Most preferably, as in the example shown in FIG. 5, in plan view, the p⁺-type contact region 18 is provided over the entire region between the pair of n⁺-type emitter regions 16.

It should be noted that, in plan view, the insulator 25 may be provided over the entire region between a pair of n⁺-type emitter regions 16 as in the example shown in FIG. 7. However, from the viewpoint of suppressing the operation of the parasitic thyristor, it is preferable that a structure similar to the examples shown in FIGS. 5 and 6 be applied to the semiconductor device 200.

Also, as in the examples shown in FIGS. 9A and 9B, the area ratio of the p⁺-type contact region 18 may increase and the area ratio of the insulator 25 may decrease as it gets closer to the outer peripheral region of the semiconductor device 200. Alternatively, as in the examples shown in FIGS. 10A and 10B, the area ratio of the insulator 25 may increase and the area ratio of the p⁺-type contact region 18 may decrease as it gets closer to the outer peripheral region of the semiconductor device 200. As in the modified example shown in FIG. 11, the p⁺-type anode region 14a and the conductive portion 20 may be omitted in the diode region R1.

Even when the insulator 25 is provided in place of the n⁺-type contact region 19, the injection of holes from the emitter electrode 2 into the p-type base region 15 in the IGBT region R3 during the operation of the diode region R1 is suppressed. As a result, the operation of the diode region R1 can be made faster, and the switching loss of the semiconductor device 200 can be reduced.

### Third Embodiment

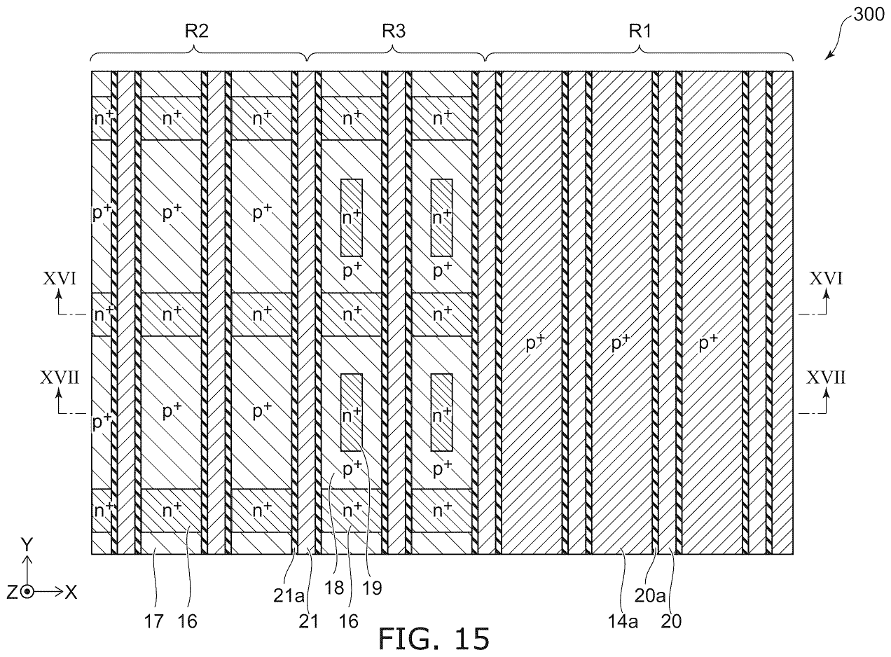

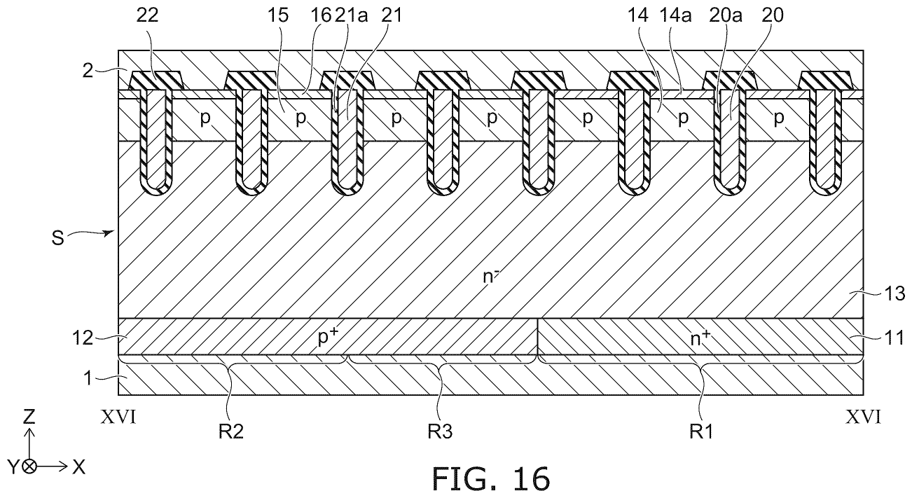

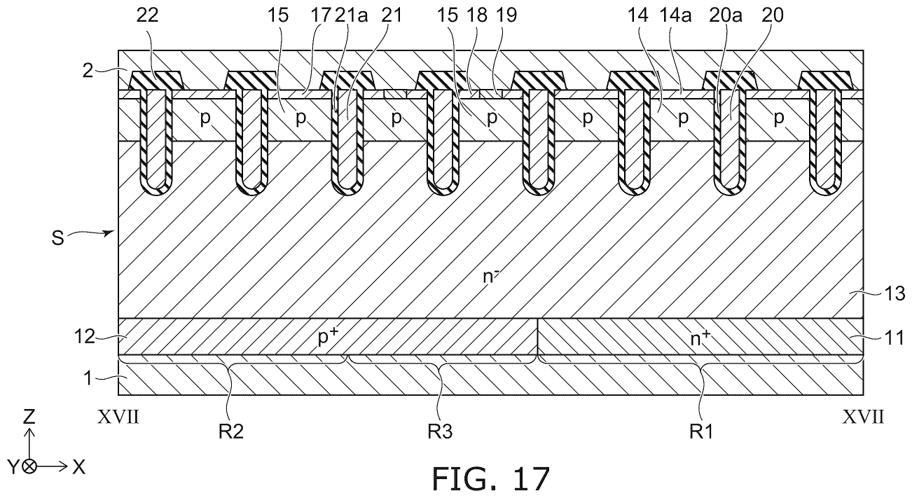

FIG. 15 is a plan view illustrating a part of a semiconductor device according to a third embodiment. FIG. 16 is a XVI-XVI cross-sectional view of FIG. 14. FIG. 17 is a XVII-XVII cross-sectional view of FIG. 15.

As shown in FIGS. 16 and 17, the semiconductor device 300 according to the third embodiment differs from the semiconductor device 100 according to the first embodiment in that the emitter electrode 2 does not include the contact portion 2a. In the semiconductor device 300, due to the absence of the contact portion 2a, the structures of the n⁺-type emitter region 16, the p⁺-type contact region 17, the p⁺-type contact region 18, and the n⁺-type contact region 19 are changed compared to those in the semiconductor device 100.

Specifically, in the IGBT region R2, the n⁺-type emitter region 16 and the p⁺-type contact region 17 are alternately provided along the Y-direction on one p-type base region 15. In the IGBT region R3, the n⁺-type emitter region 16 and the p⁺-type contact region 18 are alternately provided along the Y-direction on one p-type base region 15. The n⁺-type contact region 19 is surrounded by the p⁺-type contact region 18 along the X-Y plane (a first plane).

For example, the p-type base region 15, the n⁺-type emitter region 16, the p⁺-type contact region 17, and the p⁺-type contact region 18 are in contact with the gate insulating layer 21a. The n⁺-type contact region 19 is apart from the gate insulating layer 21a in the X-direction. Additionally, the n⁺-type contact region 19 is apart from the n⁺-type emitter region 16 in the Y-direction.

Also in the semiconductor device 300 according to the third embodiment, by providing the n⁺-type contact region 19, the injection of holes from the emitter electrode 2 into the p-type base region 15 in the IGBT region R3 during the operation of the diode region R1 is suppressed. As a result, the operation of the diode region R1 can be further accelerated, and the switching loss of the semiconductor device 300 can be reduced.

In the semiconductor device 300, the n⁺-type contact region 19 is apart from the gate insulating layer 21a in the X-direction. Therefore, when the IGBT regions R2 and R3 are in the on-state, the n⁺-type contact region 19 is positioned away from the channel. Compared to the case where the n⁺-type contact region 19 is in contact with the gate insulating layer 21a, the injection of electrons from the n⁺-type contact region 19 into the n⁻-type base region 13 can be suppressed. As a result, the current flowing from the emitter electrode 2 to the collector electrode 1 can be reduced, and the saturation current of the semiconductor device 300 can be reduced. For example, the current flowing through the semiconductor device 300 during a short-circuit can be reduced, and the occurrence of destruction due to the short-circuit can be suppressed. Therefore, it is preferable that the n⁺-type contact region 19 be apart from the gate insulating layer 21a in the X-direction.

Furthermore, the n⁺-type contact region 19 is apart from the n⁺-type emitter region 16 in the Y-direction. In this case, the p⁺-type contact region 18 can be more extensively provided in the vicinity of the n⁺-type emitter region 16 compared to the case where the n⁺-type contact region 19 is in contact with the n⁺-type emitter region 16 in the Y-direction. In the vicinity of the n⁺-type emitter region 16, the rise in electric potential of the p-type base region 15 is suppressed. As a result, the operation of the parasitic thyristor can be suppressed. Therefore, it is preferable that the n⁺-type contact region 19 be apart from the n⁺-type emitter region 16 in the Y-direction.

In the present specification, the term “or” indicates that at least one of the listed items in the sentence can be adopted.

The embodiments according to the present invention include the following features.

### Feature 1

A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
   a first semiconductor region of a first conductivity type provided in the first region,
   a second semiconductor region of a second conductivity type provided in the second region,
   a third semiconductor region of the first conductivity type provided on the first semiconductor region and the second semiconductor region,
   a fourth semiconductor region of the second conductivity type provided on the third semiconductor region, the fourth semiconductor region being located in the first region,
   a plurality of fifth semiconductor regions of the second conductivity type provided on the third semiconductor region, the plurality of fifth semiconductor regions being located in the second region and the third region,
   a plurality of gate electrodes respectively facing the plurality of fifth semiconductor regions via a plurality of gate insulating layers in the second direction,
   a plurality of sixth semiconductor regions of the first conductivity type respectively provided on the plurality of fifth semiconductor regions, the plurality of sixth semiconductor regions respectively being in contact with a plurality of contact portions of the second electrode in the second direction,
   a seventh semiconductor region of the second conductivity type provided between one of the plurality of fifth semiconductor regions and one of the plurality of contact portions in the second region, and
   an eighth semiconductor region of the second conductivity type and a ninth semiconductor region of the first conductivity type each provided between another one of the plurality of fifth semiconductor regions and another one of the plurality of contact portions in the third region.

### Feature 2

The semiconductor device according to feature 1, wherein
in the third region, the eighth semiconductor region and the ninth semiconductor region are alternately provided along a third direction, and
the third direction is perpendicular to the first direction and the second direction.

### Feature 3

The semiconductor device according to feature 1 or 2, wherein
in the third region, a position in a third direction of at least part of one of the plurality of sixth semiconductor regions is the same as a position in the third direction of at least part of the eighth semiconductor region, and
the third direction is perpendicular to the first direction and the second direction.

### Feature 4

The semiconductor device according to any one of features 1 to 3, wherein
in the third region, a pair of the sixth semiconductor regions apart from each other in the second direction are provided on one of the plurality of fifth semiconductor regions,
one of the plurality of contact portions includes
   a first portion located on the eighth semiconductor region, and
   a second portion located on the ninth semiconductor region,
at least part of the first portion is located between the pair of sixth semiconductor regions in the second direction.

### Feature 5

The semiconductor device according to any one of features 1 to 3, wherein
in the third region, a pair of the sixth semiconductor regions apart from each other in the second direction are provided on one of the plurality of fifth semiconductor regions,
one of the plurality of contact portions includes
   a first portion located on the eighth semiconductor region, and
   a second portion located on the ninth semiconductor region,
the first portion is located over an entire region between the pair of sixth semiconductor regions.

### Feature 6

The semiconductor device according to any one of features 1 to 5, wherein
in the third region, two or more sixth semiconductor regions are provided on one of the plurality of fifth semiconductor regions,
the two or more sixth semiconductor regions are apart from each other in a third direction that is perpendicular to the first direction and the second direction,
on the one of the plurality of fifth semiconductor regions, a distance in the third direction between adjacent ones of the two or more sixth semiconductor regions is greater than a length in the third direction of one of the two or more sixth semiconductor regions.

### Feature 7

The semiconductor device according to any one of features 1 to 6, wherein
a length in a third direction of the eighth semiconductor region is greater than a length in the third direction of the ninth semiconductor region, and
the third direction is perpendicular to the first direction and the second direction.

### Feature 8

The semiconductor device according to any one of features 1 to 3, wherein
in the third region, a pair of the sixth semiconductor regions apart from each other in the second direction are provided on one of the plurality of fifth semiconductor regions,
one of the plurality of contact portions includes
   a first portion located on the eighth semiconductor region, and
   a second portion located on the ninth semiconductor region,
in a region between the pair of sixth semiconductor regions, an area of the first portion along a first plane is greater than an area of the second portion along the first plane, and
the first plane is perpendicular to the first direction.

### Feature 9

The semiconductor device according to any one of features 1 to 8, wherein
the plurality of contact portions protrude toward the semiconductor layer, and
the seventh semiconductor region, the eighth semiconductor region, and the ninth semiconductor region are located below the plurality of contact portions.

### Feature 10

A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
   a first semiconductor region of a first conductivity type provided in the first region,
   a second semiconductor region of a second conductivity type provided in the second region,
   a third semiconductor region of the first conductivity type provided on the first semiconductor region and the second semiconductor region,
   a fourth semiconductor region of the second conductivity type provided on the third semiconductor region, the fourth semiconductor region being located in the first region,
   a plurality of fifth semiconductor regions of the second conductivity type provided on the third semiconductor region, the plurality of fifth semiconductor regions being located in the second region and the third region,
   a plurality of gate electrodes respectively facing the plurality of fifth semiconductor regions via a plurality of gate insulating layers in the second direction,
   a plurality of sixth semiconductor regions of the first conductivity type respectively provided on the plurality of fifth semiconductor regions, the plurality of sixth semiconductor regions respectively being in contact with a plurality of contact portions of the second electrode in the second direction,
   a seventh semiconductor region of the second conductivity type provided between first one of the plurality of fifth semiconductor regions and first one of the plurality of contact portions in the second region,
   an eighth semiconductor region of the second conductivity type provided between second one of the plurality of fifth semiconductor regions and second one of the plurality of contact portions in the third region, and
   an insulator provided between the second one of the plurality of fifth semiconductor regions and the second one of the plurality of contact portions, the insulator being arranged with the eighth semiconductor region in a third direction that is perpendicular to the first direction and the second direction.

### Feature 11

The semiconductor device according to feature 10, wherein
in the third region, the eighth semiconductor region and the insulator are alternately provided along the third direction.

### Feature 12

The semiconductor device according to feature 10 or 11, wherein
in the third region, a position in the third direction of at least part of one of the plurality of sixth semiconductor regions is the same as a position in the third direction of at least part of the eighth semiconductor region.

### Feature 13

A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
   a first semiconductor region of a first conductivity type provided in the first region,
   a second semiconductor region of a second conductivity type provided in the second region,
   a third semiconductor region of the first conductivity type provided on the first semiconductor region and the second semiconductor region,
   a fourth semiconductor region of the second conductivity type provided on the third semiconductor region, the fourth semiconductor region being located in the first region,
   a plurality of fifth semiconductor regions of the second conductivity type provided on the third semiconductor region, the plurality of fifth semiconductor regions being located in the second region and the third region,
   a plurality of gate electrodes respectively facing the plurality of fifth semiconductor regions via a plurality of gate insulating layers in the second direction,
   a plurality of sixth semiconductor regions of the first conductivity type respectively provided on the plurality of fifth semiconductor regions,
   a seventh semiconductor region of the second conductivity type provided on first one of the plurality of fifth semiconductor regions, the seventh semiconductor region being located in the second region,
   an eighth semiconductor region of the second conductivity type provided on second one of the plurality of fifth semiconductor regions, the eighth semiconductor region being located in the third region, and
   a ninth semiconductor region of the first conductivity type provided on the second one of the plurality of fifth semiconductor regions, the ninth semiconductor region being located in the third region and surrounded by the eighth semiconductor region along a first plane that is perpendicular to the first direction.

### Feature 14

The semiconductor device according to claim 13, wherein
in the third region, the sixth semiconductor region and the eighth semiconductor region are alternately provided on the second one of the plurality of fifth semiconductor regions along a third direction,
the third direction is perpendicular to the first direction and the second direction,
a plurality of the ninth semiconductor regions are respectively surrounded by a plurality of the eighth semiconductor regions.

According to the embodiments described above, a semiconductor device capable of reducing switching loss when the diode operates is provided.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
a first semiconductor region of a first conductivity type provided in the first region,
a second semiconductor region of a second conductivity type provided in the second region,
a third semiconductor region of the first conductivity type provided on the first semiconductor region and the second semiconductor region,
a fourth semiconductor region of the second conductivity type provided on the third semiconductor region, the fourth semiconductor region being located in the first region,
a plurality of fifth semiconductor regions of the second conductivity type provided on the third semiconductor region, the plurality of fifth semiconductor regions being located in the second region and the third region,
a plurality of gate electrodes respectively facing the plurality of fifth semiconductor regions via a plurality of gate insulating layers in the second direction,
a plurality of sixth semiconductor regions of the first conductivity type respectively provided on the plurality of fifth semiconductor regions, the plurality of sixth semiconductor regions respectively being in contact with a plurality of contact portions of the second electrode in the second direction,
a seventh semiconductor region of the second conductivity type provided between one of the plurality of fifth semiconductor regions and one of the plurality of contact portions in the second region, and
an eighth semiconductor region of the second conductivity type and a ninth semiconductor region of the first conductivity type each provided between another one of the plurality of fifth semiconductor regions and another one of the plurality of contact portions in the third region.

2. The semiconductor device according to claim 1, wherein
in the third region, the eighth semiconductor region and the ninth semiconductor region are alternately provided along a third direction, and
the third direction is perpendicular to the first direction and the second direction.

3. The semiconductor device according to claim 1, wherein
in the third region, a position in a third direction of at least part of one of the plurality of sixth semiconductor regions is the same as a position in the third direction of at least part of the eighth semiconductor region, and
the third direction is perpendicular to the first direction and the second direction.

4. The semiconductor device according to claim 1, wherein
in the third region, a pair of the sixth semiconductor regions apart from each other in the second direction are provided on one of the plurality of fifth semiconductor regions,
one of the plurality of contact portions includes
a first portion located on the eighth semiconductor region, and
a second portion located on the ninth semiconductor region,
at least part of the first portion is located between the pair of sixth semiconductor regions in the second direction.

5. The semiconductor device according to claim 1, wherein
in the third region, a pair of the sixth semiconductor regions apart from each other in the second direction are provided on one of the plurality of fifth semiconductor regions,
one of the plurality of contact portions includes
a first portion located on the eighth semiconductor region, and
a second portion located on the ninth semiconductor region,
the first portion is located over an entire region between the pair of sixth semiconductor regions.

6. The semiconductor device according to claim 1, wherein
in the third region, two or more sixth semiconductor regions are provided on one of the plurality of fifth semiconductor regions,
the two or more sixth semiconductor regions are apart from each other in a third direction that is perpendicular to the first direction and the second direction,
on the one of the plurality of fifth semiconductor regions, a distance in the third direction between adjacent ones of the two or more sixth semiconductor regions is greater than a length in the third direction of one of the two or more sixth semiconductor regions.

7. The semiconductor device according to claim 1, wherein
a length in a third direction of the eighth semiconductor region is greater than a length in the third direction of the ninth semiconductor region, and
the third direction is perpendicular to the first direction and the second direction.

8. The semiconductor device according to claim 1, wherein
in the third region, a pair of the sixth semiconductor regions apart from each other in the second direction are provided on one of the plurality of fifth semiconductor regions,
one of the plurality of contact portions includes
a first portion located on the eighth semiconductor region, and
a second portion located on the ninth semiconductor region,
in a region between the pair of sixth semiconductor regions, an area of the first portion along a first plane is greater than an area of the second portion along the first plane, and
the first plane is perpendicular to the first direction.

9. The semiconductor device according to claim 1, wherein
the plurality of contact portions protrude toward the semiconductor layer, and
the seventh semiconductor region, the eighth semiconductor region, and the ninth semiconductor region are located below the plurality of contact portions.

10. A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
a first semiconductor region of a first conductivity type provided in the first region,
a second semiconductor region of a second conductivity type provided in the second region,
a third semiconductor region of the first conductivity type provided on the first semiconductor region and the second semiconductor region,
a fourth semiconductor region of the second conductivity type provided on the third semiconductor region, the fourth semiconductor region being located in the first region,
a plurality of fifth semiconductor regions of the second conductivity type provided on the third semiconductor region, the plurality of fifth semiconductor regions being located in the second region and the third region,
a plurality of gate electrodes respectively facing the plurality of fifth semiconductor regions via a plurality of gate insulating layers in the second direction,
a plurality of sixth semiconductor regions of the first conductivity type respectively provided on the plurality of fifth semiconductor regions, the plurality of sixth semiconductor regions respectively being in contact with a plurality of contact portions of the second electrode in the second direction,
a seventh semiconductor region of the second conductivity type provided between first one of the plurality of fifth semiconductor regions and first one of the plurality of contact portions in the second region,
an eighth semiconductor region of the second conductivity type provided between second one of the plurality of fifth semiconductor regions and second one of the plurality of contact portions in the third region, and
an insulator provided between the second one of the plurality of fifth semiconductor regions and the second one of the plurality of contact portions, the insulator being arranged with the eighth semiconductor region in a third direction that is perpendicular to the first direction and the second direction.

11. The semiconductor device according to claim 10, wherein
in the third region, the eighth semiconductor region and the insulator are alternately provided along the third direction.

12. The semiconductor device according to claim 10, wherein
in the third region, a position in the third direction of at least part of one of the plurality of sixth semiconductor regions is the same as a position in the third direction of at least part of the eighth semiconductor region.

13. A semiconductor device comprising:
a first electrode;
a second electrode apart from the first electrode in a first direction; and
a semiconductor layer provided between the first electrode and the second electrode, the semiconductor layer including a first region, a second region, and a third region located between the first region and the second region in a second direction that is perpendicular to the first direction, the semiconductor layer including
a first semiconductor region of a first conductivity type provided in the first region,
a second semiconductor region of a second conductivity type provided in the second region,
a third semiconductor region of the first conductivity type provided on the first semiconductor region and the second semiconductor region,
a fourth semiconductor region of the second conductivity type provided on the third semiconductor region, the fourth semiconductor region being located in the first region,
a plurality of fifth semiconductor regions of the second conductivity type provided on the third semiconductor region, the plurality of fifth semiconductor regions being located in the second region and the third region,
a plurality of gate electrodes respectively facing the plurality of fifth semiconductor regions via a plurality of gate insulating layers in the second direction,
a plurality of sixth semiconductor regions of the first conductivity type respectively provided on the plurality of fifth semiconductor regions,
a seventh semiconductor region of the second conductivity type provided on first one of the plurality of fifth semiconductor regions, the seventh semiconductor region being located in the second region,
an eighth semiconductor region of the second conductivity type provided on second one of the plurality of fifth semiconductor regions, the eighth semiconductor region being located in the third region, and
a ninth semiconductor region of the first conductivity type provided on the second one of the plurality of fifth semiconductor regions, the ninth semiconductor region being located in the third region and surrounded by the eighth semiconductor region along a first plane that is perpendicular to the first direction.

14. The semiconductor device according to claim 13, wherein
in the third region, the sixth semiconductor region and the eighth semiconductor region are alternately provided on the second one of the plurality of fifth semiconductor regions along a third direction,
the third direction is perpendicular to the first direction and the second direction,
a plurality of the ninth semiconductor regions are respectively surrounded by a plurality of the eighth semiconductor regions.
